(19) United States
(12) Patent Application Publication
(10) Pub. No.: US 2014/0120825 A1
(43) Pub. Date: May 1, 2014

(54) ROOM AND CONTAINER DATA CENTER IN THE ROOM

(71) Applicant: HON HAI PRECISION INDUSTRY CO., LTD., New Taipei (TW)

(72) Inventors: TAI-WEI LIN, New Taipei (TW); SHIH-CHIEH CHEN, New Taipei (TW)

(73) Assignee: HON HAI PRECISION INDUSTRY CO., LTD., New Taipei (TW)

(21) Appl. No.: 13/709,081

(22) Filed: Dec. 10, 2012

(30) Foreign Application Priority Data
Oct. 30, 2012 (TW) 101140109

(51) Int. Cl. H05K 5/02

(52) U.S. Cl. CPC H05K 5/0213
USPC 454/184

(57) ABSTRACT

A container data center includes a container and an air duct. The container includes a sidewall defining an air inlet in a lower portion of the sidewall and an air outlet in an upper portion of the sidewall. The air duct includes an air pipe and a hollow connecting portion connected to the outlet. When the container data center operates, air flows into the container through the inlet to dissipate heat for the container. The heated air then flows out of the container through the outlet and the air duct.

### BACKGROUND

1. Technical Field

The present disclosure relates to a room for receiving a container data center.

2. Description of Related Art

After container data centers are transported to an operation site , the container data centers are arranged in a room at some times. During operation, the container data centers generate a great amount of heat in the room. The heat surrounds the container data centers, and is difficult to be exhausted out of the room.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic, isometric view of an exemplary embodiment of a room, wherein the room includes a container data center.

FIG. 2 is an enlarged view of the container data center of FIG. 1.

FIG. 3 is an exploded, isometric view of the container data center of FIG. 2

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

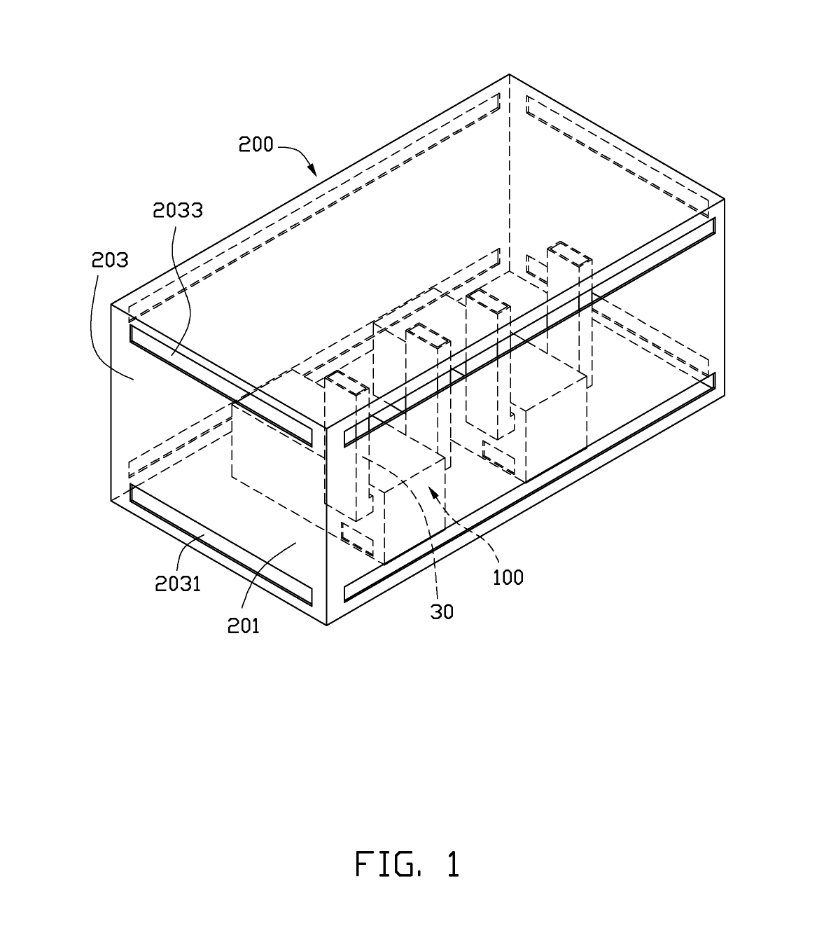

Referring to FIG. 1, an embodiment of a room 200 includes a plurality of container data centers 100 arranged in the room 200. The room 200 includes a bottom wall 201 and a plurality of sidewalls 203 extending from sides of the bottom wall 201. The container data centers 100 are supported on the bottom wall 201. An air inlet 2031 and an air outlet 2033 are defined in a lower portion and an upper portion of each sidewall 203, respectively.

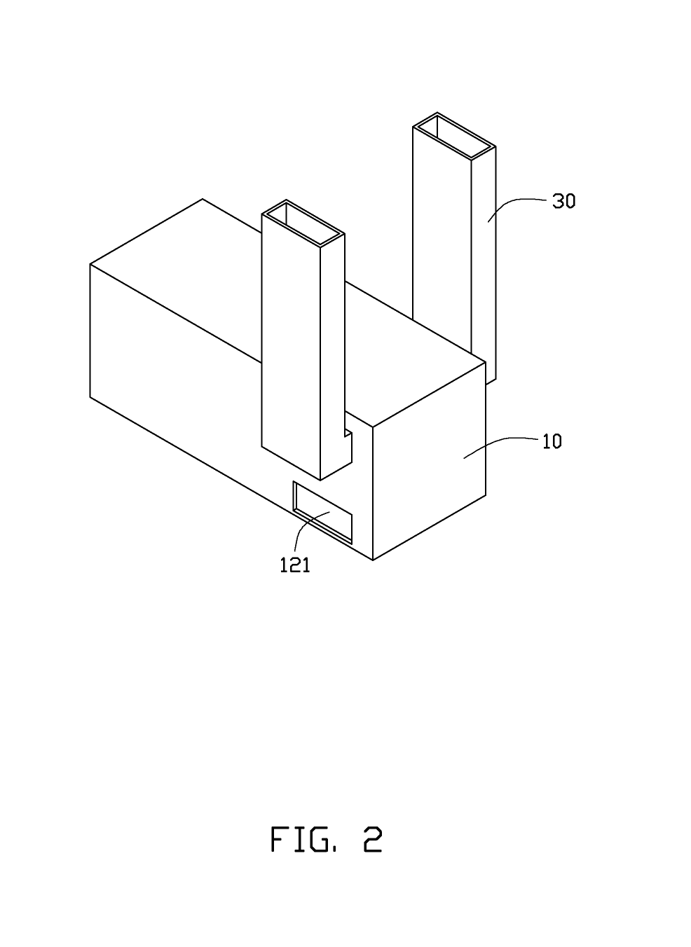

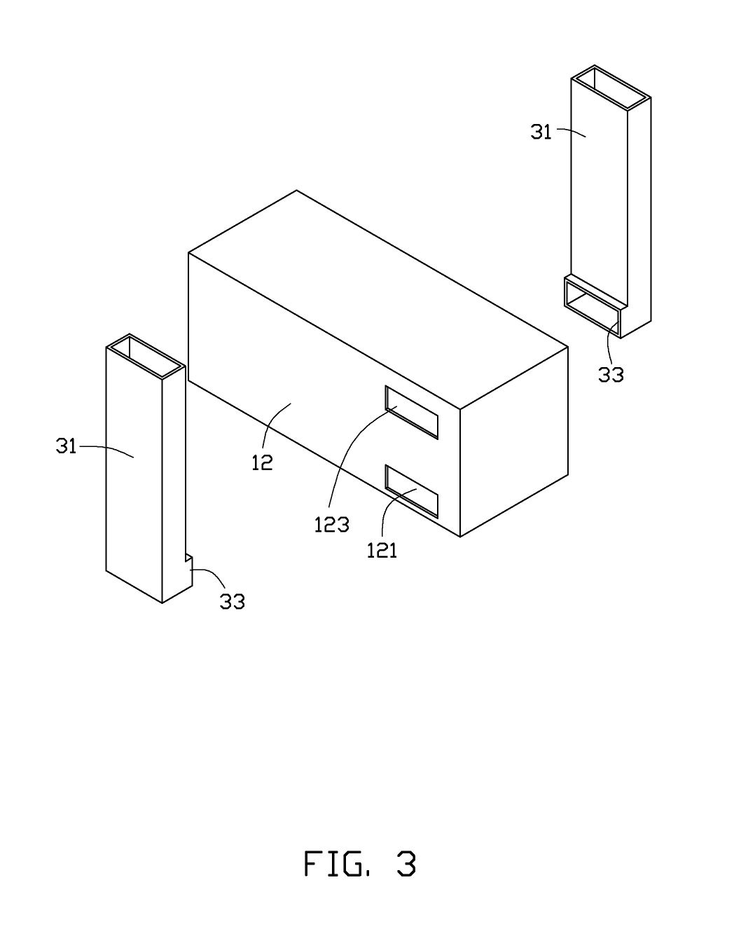

Referring to FIG. 2 and FIG. 3, each container data center 100 includes a container 10 and two air ducts 30 located at opposite sides of the container 10. The container 10 includes two side plates 12 each defining an inlet 121 in a lower portion and an outlet 123 in an upper portion. Each air duct 30 is substantially L-shaped and includes an upright air pipe 31 and a hollow connecting portion 33 connected to a lower end of the air pipe 31. The connecting portion 33 is fixed to one of the side plates 12 and communicates with the outlet 123.

When the container data center 100 operates, air flows into the container 10 through the air inlets 2031 and the inlets 121 in that order to dissipate heat for the container 10. The heated air then flows out of the container 10 through the outlets 123 and the air ducts 30, to enter an upper portion in the room 200 and then be exhausted out of the room 100 through the air outlets 2033.

In the embodiment, the air ducts 30 can exhaust the heated air to the upper portion of the room 200. Thus, the exhausted heated air is away from the container 10, which is beneficial for cooling the container data center 100.

Even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A container data center, comprising:
a container comprising a sidewall defining an inlet in a lower portion and an outlet in an upper portion; and
an air duct fixed to an outer surface of the sidewall and communicating with the outlet.

2. The container data center of claim 1, wherein the air duct comprises an upright air pipe and a hollow connecting portion connected to a lower end of the air pipe, the connecting portion communicates with the outlet.

3. A room receiving container data centers, comprising:
a bottom wall;
a sidewall extending up from one side of the bottom wall and defining an air inlet in a lower portion and an air outlet in an upper portion respectively; and
a plurality of container data centers supported on the bottom wall;
wherein each of the container data centers comprises a container, the container comprises a sidewall defining an inlet in a lower portion and an outlet in an upper portion, and an air duct fixed to an outer surface of the sidewall and communicating with the outlet; and
wherein when the container data center operates, air flows into the container through the air inlet and the inlet of each container in that order to dissipate heat, heated air then flows out of the container through the outlet and the air duct, to enter an upper portion in the room and be exhausted out of the room through the air outlet.

4. The room of claim 3, wherein the air duct comprises an upright air pipe and a hollow connecting portion connected to a lower portion of the air pipe, the connecting portion communicates with the outlet.
